(19) United States
(12) Patent Application Publication
(10) Pub. No.: US 2024/0404831 A1
(43) Pub. Date: Dec. 5, 2024

(54) ELECTRONIC DEVICE AND MANUFACTURING METHOD THEREOF

(71) Applicant: InnoLux Corporation, Miao-Li County (TW)

(72) Inventors: Ker-Yih KAO, Miao-Li County (TW); Zheng-Wei WU, Miao-Li County (TW); Ju-Li WANG, Miao-Li County (TW)

(73) Assignee: InnoLux Corporation, Miao-Li County (TW)

(21) Appl. No.: 18/655,360

(22) Filed: May 6, 2024

Related U.S. Application Data
(60) Provisional application No. 63/469,549, filed on May 30, 2023.

(30) Foreign Application Priority Data
Feb. 20, 2024 (CN) 202410186853.2

(51) Int. Cl. H01L 21/304; H01L 21/56; H01L 23/31

(52) U.S. Cl. CPC H01L 21/304; H01L 21/565; H01L 23/31

(57) ABSTRACT

An electronic device includes a chip, a protection, a molding layer and a redistribution structure layer. The chip has an active surface and a first side surface connected to the active surface. The protection layer is disposed on the active surface of the chip and has a second side surface. The molding layer surrounds the chip and the protection layer. The redistribution structure layer is disposed on the molding layer, on the protection layer and electrically connected to the chip. The roughness of the first side surface is different from the roughness of the second side surface.

### CROSS REFERENCE TO RELATED APPLICATION

This application claims the benefit of U.S. Provisional Application No. 63/469,549, filed on May 30, 2023. The content of the application is incorporated herein by reference.

### BACKGROUND OF THE DISCLOSURE

### 1. Field of the Disclosure

The present disclosure relates to an electronic device and the manufacturing method thereof, and in particular to an electronic device which has improved structural stability and reliability and the manufacturing method thereof.

### 2. Description of the Prior Art

During the manufacturing process of an electronic device, through a cutting area an insulation or a dielectric layer therein is cut. According to the development trend of electronic devices, a low dielectric constant material layer is beneficial for the electronic devices to exhibit electronic properties such as lower leakage current. However, the material properties of the low dielectric constant material layer itself are relatively fragile. Therefore, the low dielectric constant material layer is prone to flaws such as chipping or cracking when the low dielectric constant material layer is subjected to cutting. The chipped or cracked dielectric layer is prone to jeopardize the structural stability of the electronic device after cutting and the reliability of the electronic device.

In view of these, it is needed to continuously research the manufacturing method of an electronic device in the field to improve the problem of chipping or cracking of the dielectric constant material layer in the electronic device after cutting, and to help further enhance the structural stability and the reliability of the electronic device after cutting.

### SUMMARY OF THE DISCLOSURE

Some embodiments of the present disclosure provide a method for manufacturing an electronic device, which is beneficial to improve the problem of chipping or cracking of the dielectric constant material layer in the electronic device after cutting. Therefore, it is helpful to further enhance the structural stability and the reliability of the electronic device after cutting.

According to some embodiments of the present disclosure, a method of manufacturing an electronic device is provided. First, a substrate layer is provided. Second, a circuit structure is formed on one side of the substrate layer. Then, a protection layer is attached to the circuit structure. Later, a first cutting step is carried out to cut the protection layer to expose a portion of the substrate layer. Next, a second cutting step is carried out to cut the substrate layer to form a plurality of chips. The first cutting step is different from the second cutting step.

According to some other embodiments of the present disclosure, an electronic device provided by the present disclosure includes a chip, a protection layer, a molding layer, and a redistribution structure layer. The chip has an active surface and a first side surface connected to the active surface. The protection layer is disposed on the active surface of the chip and has a second side surface. The molding layer surrounds the chip and the protection layer. The redistribution structure layer is disposed on the molding layer, on the protection layer and electrically connected to the chip. The roughness of the first side surface is different from the roughness of the second side surface.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1, FIG. 1A, FIG. 1B and FIG. 1C respectively illustrate a schematic process diagram of an embodiment of a method for forming an electronic device according to the present disclosure, and FIG. 1, FIG. 1A, FIG. 1B and FIG. 1C respectively represent component structures in a schematic cross-sectional view.

FIG. 2, FIG. 2A, FIG. 2B and FIG. 2C are respectively schematic process diagrams of a variant embodiment of a method for forming an electronic device according to the present disclosure, and FIG. 2, FIG. 2A, FIG. 2B and FIG. 2C respectively represent the component structures in a schematic cross-sectional view.

FIG. 3, FIG. 3A, FIG. 3B, FIG. 3C, FIG. 3D and FIG. 3E respectively illustrate a process diagram of an embodiment of a method for forming an electronic device by subsequent packaging and forming a redistribution structure layer according to the present disclosure, and FIG. 3, FIG. 3A, FIG. 3B, FIG. 3C, FIG. 3D and FIG. 3E respectively illustrate the component structures in schematic cross-sectional views.

FIG. 4 illustrates a schematic cross-sectional view of a variant embodiment corresponding to the electronic device 100 illustrated in FIG. 3B.

FIG. 5 illustrates a schematic cross-sectional view of a variant embodiment corresponding to the electronic device illustrated in FIG. 3E.

### DETAILED DESCRIPTION

The present disclosure may be understood by reference to the following detailed description, taken in conjunction with the drawings as described below. For purposes of illustrative clarity understood, various drawings of this disclosure show a portion of the electronic device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not in function.

In the following description and in the claims, the terms “include”, “comprise” and “have” are used in an open-ended fashion, and thus should be interpreted to mean “include, but not limited to . . . ”.

It will be understood that when an element or a film layer is referred to as being “on another component or on another layer” or “connected to another component or to another film layer”, it may be directly on or directly connected to the other element or film layer, or intervening elements or film layers may be presented (not directly). In contrast, when an element is referred to as being “directly on” or “directly connected to” another element or film layer, there are no intervening elements or film layers present.

In some embodiments of the present disclosure, terms such as “connection”, “interconnection”, etc. regarding bonding and connection, unless specifically defined, may refer to two structures which are in direct contact with each other, or are not in direct contact with each other. It is possible that there are other structures located between these two structures. Moreover, terms such as “connection”, “interconnection” may also include the case where both structures are movable or both structures are fixed. In addition, the terms “electrical connected” or “electrical coupled” includes any direct and indirect electrical connection means.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

The term “disposed on” is used only to facilitate the description of the manufacturing method with no intention to limit the process steps or sequence.

In the following description, roughness is defined as: when observed with a scanning electron microscope (SEM), on the surface of a given component, such as a stud, it may be seen that the peaks and valleys of the undulating surface have a distance difference of 0.15 μm to 1 μm. Measurement to determine the roughness may include using a scanning electron microscope, a transmission electron microscope (TEM), etc. to observe the surface undulations at the same appropriate magnification to compare the undulations by capturing unit length (for example, 10 μm). Here, “appropriate magnification” means that at least 10 undulating peaks are observed on at least one surface under the field of view at this magnification. According to some embodiments, a connecting component may be used to contact a solder ball, but is not limited thereto.

It should be noted that the technical features in different embodiments described in the following may be replaced, recombined, or mixed with one another to constitute another embodiment without departing from the spirit of the present disclosure.

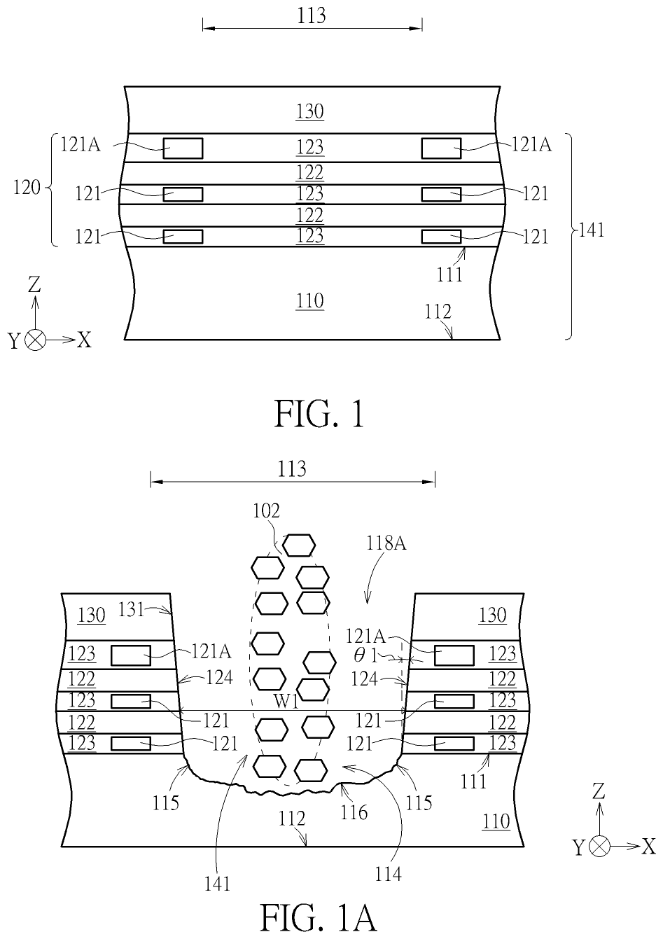

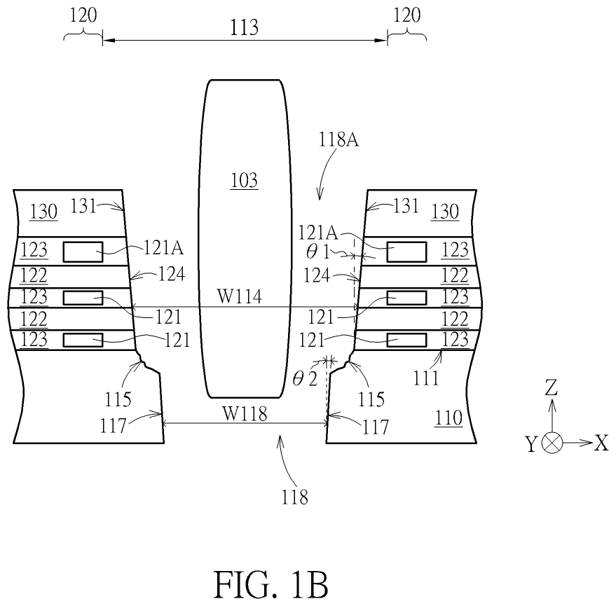

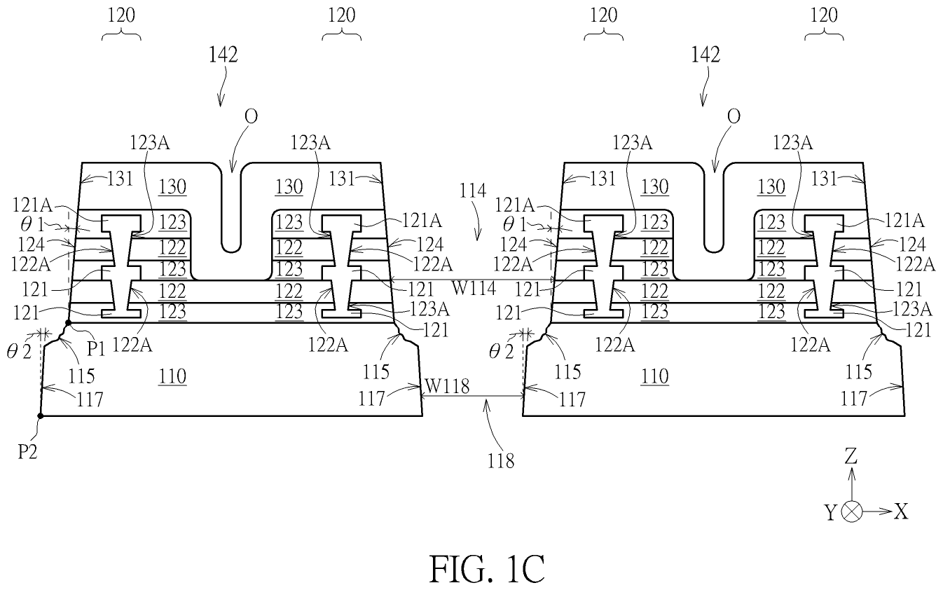

FIG. 1, FIG. 1A, FIG. 1B and FIG. 1C respectively illustrate a schematic process diagram of an embodiment of a method for forming an electronic device according to the present disclosure. FIG. 1, FIG. 1A, FIG. 1B and FIG. 1C respectively represent component structures in a schematic cross-sectional view. FIG. 1C is a schematic cross-sectional view of a variant embodiment of the component structures of the electronic device. In the present disclosure, the electronic device may be applied to a power module, to a semiconductor packaging device, to a display device, to a light emitting device, to a backlight device, to an antenna device, to a sensing device, to a splicing device or to a flexible/bendable device, but the present disclosure is not limited thereto. An electronic device may also include a semiconductor chip, or a functional stack layer formed by staggered stacks of multiple metal layers (copper layers and seed layers) and multiple insulation layers, such as a redistribution layer (RDL), but the present disclosure is not limited thereto. The term “flexible/bendable” here means that the material may be curved, bent, folded, rolled, flexible, stretched and/or other similar deformations, to represent at least one of the possible deformation methods as mentioned above, but “flexible/bendable” is not limited to the above-mentioned deformation methods. The antenna device may be a liquid crystal type antenna device or a non-liquid crystal type antenna device. In the present disclosure, an electronic component may include a passive component, an active component, or a combination thereof, such as a capacitor, a resistor, an inductor, a varactor diode, a variable capacitor, a filter, a diode, a transistor, a sensor, a microelectromechanical system component (MEMS), a liquid crystal chip, etc. but the present disclosure is not limited thereto. A diode may include a light emitting diode or a non-light emitting diode. A diode may include a P-N junction diode, a PIN diode or a constant current diode. A light emitting diodes may include, for example, an organic light emitting diode (OLED), a submillimeter light emitting diodes (mini LED), a micro light emitting diode (micro LED), and a quantum dot light emitting diode (quantum dot LED), a fluorescence (fluorescence) diode, a phosphor (phosphor) diode or other suitable materials, or a combination of the above, but the present disclosure is not limited thereto. An electronic component may include a die or a light emitting diode die (LED die), which may be a chip made of silicon (Si), gallium arsenide (GaAs), gallium nitride (GaN), silicon carbide (Sic), sapphire (sapphire) or a glass substrate, but the present disclosure is not limited thereto. In another embodiment, the die may include a semiconductor packaging component, such as a chip size package (CSP) component, but the present disclosure is not limited thereto. In another embodiment, the chip may be any flip-chip bonding component, such as integrated circuits (IC), a transistor, a controlled silicon rectifier, a valve, a thin film transistor, a capacitor, an inductor, a variable capacitor, a filter, a resistor, a diode, a microelectromechanical system components (MEMS), a liquid crystal chip, etc. but the present disclosure is not limited thereto. In addition, the chip may include, for example, a diode or a semiconductor die, but the present disclosure is not limited thereto. The die may be a known good die (KGD), which may include various electronic components, such as (but not limited to) wires, transistors, circuit boards, etc. Adjacent dies may have different functions, such as integrated circuits, RFICs, and D-RAMs, but the present disclosure is not limited thereto. If the electronic device is used in packaging, for example, in wafer-level package (WLP), panel-level packaging (PLP), for example, to include packaging methods such as chip-first or chip last RDL first, but the present disclosure is not limited thereto. It should be noted that conductive trace of the packaging methods including fan-in or fan-out by redistribution structure layer. It should be noted that the electronic device may be any combination of the above, but the present disclosure is not limited thereto. Each embodiment of the present disclosure illustrates a combination of a plurality of electronic units, a RDL structure, a metal layer, an insulation layer, a connecting component, a bonding component, and an input/output pad (I/O pad) packaged with a molding insulation layer. The electronic unit of the present disclosure may be an electronic device in the form of a fan-out package as an example, but the present disclosure is not limited thereto. In the following, a packaging device is used as an example of an electronic device to illustrate the present disclosure, but it is not limited thereto. The dielectric material of the redistribution structure layer may include an organic dielectric material, an inorganic dielectric material, or a combination of the above or other dielectric materials which may be used for packaging, but the present disclosure is not limited thereto. An organic dielectric material may include, for example, polybenzoxazole (PBO), benzocyclobutene (BCB), acrylic, ABF (Ajinomoto build-up film) materials, polyimide (PI), polyamide, other suitable materials, or a combination thereof for use in packaging, but the present disclosure is not limited thereto. An inorganic dielectric material may include, for example, silicon oxide, silicon nitride, aluminum oxide, siloxane, other suitable materials, or a combination thereof for use in packaging, but the present disclosure is not limited thereto.

The X direction and the Y direction in FIG. 1 to FIG. 1C represent the plane direction of the substrate layer 110, the Z direction is the normal direction of the substrate layer 110, or may be regarded as the stacking direction of the material layers of the multi-layer metal layers and the insulation layers in the substrate layer 110. The X direction and the Y direction are respectively perpendicular to the Z direction. Please refer to FIG. 1; the manufacturing method of the electronic device of the present disclosure includes first providing a substrate layer 110. The substrate layer 110 may include a wafer. The wafer may include, for example, silicon base material, doped silicon material, gallium nitride (GaN) material or other semiconductor materials, glass, ceramics, an organic material, a combination of the above or other suitable materials, but the present disclosure is not limited thereto. The substrate layer 110 has two opposite sides, such as a first side 111 and a second side 112, i.e. a bottom surface 112, opposite to the first side 111. According to some embodiments, a circuit structure 120 is disposed on the first side 111 of the substrate layer 110, and the side of the substrate layer 110 which has the circuit structure 120 may be referred to as an active surface. Therefore, the chip 141 may include the substrate layer 110 and the circuit structure 120 disposed on one side of the substrate layer 110. The circuit structure 120 may be provided with a cutting region 113. According to some embodiments, a cutting step may be carried out in the cutting region 113 through some suitable cutting methods to separate the substrate layer 110 and the circuit structure 120, thereby obtaining a plurality of chips.

The circuit structure 120 may include at least one metal layer 121, at least one insulation layer 122, and at least one insulation layer 123. The metal layer 121 may also include a metal pad 121A disposed on the top layer and to serve as an input/output terminal bonding pad (I/O pad). According to some embodiments, the circuit structure 120 may include a transistor, such as include a gate, a drain, and a source, but the present disclosure is not limited thereto. For example, the transistor may be a metal oxide semiconductor field effect transistor (MOSFET). In other words, the chip may output or input signals, such as output voltage or current, through the circuit structure 120. According to some embodiments, the metal layer may serve as an alignment mark to facilitate the alignment during the cutting step, the chip transferring step, or other steps. According to some embodiments, stacked metal layers or metal layers which overlap one another may be disposed adjacent to the cutting region. The metal layers which overlap one another may serve as walls, for example, to buffer the stress generated by the cutting step and reduce the risk of chipping or cracking of the circuit structure, but the present disclosure is not limited thereto. In FIG. 1, it is illustrated that two metal layers 121 and one metal pad 121A are respectively embedded in three insulation layers 123, but the present disclosure is not limited thereto. An insulation layer 122 is disposed between adjacent metal layers 121 to form a circuit structure 120. The metal layer 121 may include copper, nickel, gold, titanium, molybdenum, aluminum, tantalum or other suitable materials, but the present disclosure is not limited thereto. The materials of the insulation layer 122 and the insulation layer 123 may be the same or different, and may include a dielectric material such as an organic dielectric material, an inorganic dielectric material, or a combination of the above for use in packaging, but the present disclosure is not limited thereto. Please refer to the above for the details. The insulation layer 122 and the insulation layer 123 may include a porous material of a low dielectric constant, such as a porous material of a dielectric constant lower than 2.4, a porous material of a dielectric constant lower than 2.0, a porous material of a dielectric constant lower than 1.9, but the present disclosure is not limited thereto. The metal pad 121A for use as an input-output terminal bonding pad may be electrically connected to the metal layer 121 and serve as an input-output terminal for the metal layer 121 to be electrically connected to the exterior. According to some embodiments, the metal layer 121 may be disposed in the cutting region 113. The formation process of the circuit structure 120 may include processes such as photolithography, etching, cleaning, impurity diffusion, ion implantation, and thin film deposition, so that the metal layer 121 and/or the metal pad 121A in different layers may be electrically connected to one another through the through hole 122A or through the through hole 123A, but the present disclosure is not limited thereto.

Second, as shown in FIG. 1, the protection layer 130 is formed on the circuit structure 120. For example, the protection layer 130 may be provided on the circuit structure 120 by attachment, by deposition or by coating, but the present disclosure is not limited thereto. For example, the protection layer 130 may cover the surface of the circuit structure 120. For example, the protection layer 130 may cover the surface of the circuit structure 120 along the topography of the circuit structure 120. The protection layer 130 may include, for example, an organic material with filler. The particle size of the filler may be 0.05 μm to 10 μm. The thickness of the protection layer 130 may be 10 μm to 30 μm. The organic material may include, for example, photosensitive polyimide (PSPI), polyimide, epoxy, polymer, a combination of the above, or other suitable materials, but the present disclosure is not limited thereto. The coefficient of thermal expansion (CTE) of the protection layer 130 may be, for example, 10 ppm/° C. to 40 ppm/° C., and the Young's modulus of the protection layer 130 may be, for example, 3 GPa to 15 GPa. The tensile strength of the protection layer 130 may be, for example, 50 MPa to 110 MPa, but the present disclosure is not limited thereto. According to some embodiments, along the Z direction, the thickness of the protection layer 130 may be greater than the thickness of the circuit structure 120. For example, in the same cross-sectional view, the maximum thickness of the protection layer 130 may be greater than the maximum thickness of the circuit structure 120. According to some embodiments, a ratio of the thickness of the protection layer 130 to the thickness of the circuit structure 120 may be greater than or equal to 1.1 and less than or equal to 2.5, or according to some embodiments, a ratio of the thickness of the protection layer 130 to the thickness of the circuit structure 120 may be greater than or equal to 1.3 and less than or equal to 2.3. Through the above design, forming the protection layer 130 on the circuit structure 120 may reduce the damage to the circuit structure 120 owing to the cutting steps or other steps, but the present disclosure is not limited thereto. The thickness referred to in this disclosure may be measured along the normal direction of the substrate layer 110, that is, the Z direction as shown in the figures. In addition, the X direction and the Y direction are perpendicular to the Z direction respectively, and the X direction is perpendicular to the Y direction.

Please continue to refer to FIG. 1A. Then the protection layer 130 is patterned to expose a side surface of the circuit structure 120 and a portion of the substrate layer 110. Specifically speaking, a first cutting step is carried out after the protection layer 130 covers the surface of the circuit structure 120. The first cutting step may cut the protection layer 130, cut the insulation layer 122 and the insulation layer 123 of the circuit structure 120, and cut a portion of the substrate layer 110 from the cutting region 113. After the first cutting step, a portion the substrate layer 110 disposed in the cutting region 113 may be exposed. The exposed portion of the substrate layer 110 may form a groove 114. According to some examples of the present disclosure, the first cutting step may cut the protection layer 130 to form an inclined second side surface 131, cut the circuit structure 120 to form a continuously inclined side surface 124, and cut the exposed portion of the substrate layer 110 to form a groove 114 with a curved concave surface 116 and to form a curved edge adjacent to the circuit structure 120, namely a first side surface 115, where the first side surface 115 connects the concave surface 116, where the first side surface 115 may have a wavy profile. The second side surface 131 of the protection layer 130 and the inclined side surface 124 of the insulation layer 122 in the circuit structure 120 form a continuous slope. According to some embodiments of the present disclosure, the first cutting step may reduce the possibility of forming an undesirable chipping or cracking flaw on the exposed side surface 124 of the insulation layer 122. The wavy shape referred to in the present disclosure means that a line which connects the positions of each point is not straight. For example, the line connecting each point is not along the X direction, not along Y direction, and not along Z direction.

Please continue to refer to FIG. 1B. After the first cutting step, a second cutting step may be further carried out. The second cutting step may proceed to cut the substrate layer 110 along the cutting region 113 from the groove 114 formed in the first cutting step in FIG. 1A, and cut the substrate layer 110 to form the opening 118. That is to say, the substrate layer 110, the circuit structure 120 disposed on the substrate layer 110 and the protection layer 130 disposed on the circuit structure are disconnected through a singulation step to form a plurality of chip 142, as shown in FIG. 1C. According to some examples of the present disclosure, the opening 118 is disposed in the groove 114, so the width W118 of the opening 118 along the X direction is smaller than the width W114 of the groove 114 along the X direction. According to some other examples of the present disclosure, the second cutting step may cut the substrate layer 110 to form a continuous third side surface 117, while the third side surface 117 connects the second side surface 131 via the first side surface 115 and the side surface 124 to define a side edge of the chip 142. According to some embodiments, the steps of forming the circuit structure 120 may define at least one opening O through a patterning process so that the protection layer 130 attached to the surface of the circuit structure 120 extends into the opening O. Through the above design, the contact surface between the protection layer 130 and the circuit structure 120 may be increased, thereby improving the bonding quality, but the present disclosure is not limited thereto. As shown in FIG. 1C, each insulation layer 122/123 of the circuit structure 120 contacting the protection layer 130 may have a rounded corner to reduce the risk of cracking of the protection layer 130 or improve the bonding quality of the interface, but the present disclosure is not limited thereto.

Different cutting conditions may be used to respectively carry out the first cutting step and the second cutting step. That is to say, in some embodiments of the present disclosure, the first cutting step is different from the second cutting step so that a roughness of the first side surface 115, a roughness of the side surface 124, and a roughness of the second side surface 131 formed in the first cutting step may be different from a roughness of the third side surface 117 formed by the second cutting step. According to some examples of the present disclosure, the cutting conditions of the first cutting step may be milder than the cutting conditions of the second cutting step thereby reducing the possibility of forming an undesirable chipping or cracking flaw on the exposed side surface 124 of the circuit structure 120. Different cutting conditions referred to in the present disclosure for example, the first cutting step may include laser 102, and the second cutting step may include physical cutting, such as cutting with a dicing saw 103, but the present disclosure is not limited thereto. Alternatively, the laser 102 which is used for cutting may have different wavelengths or widths, for example, a laser with a wavelength of 355 nanometer (nm) may be used to cut the protection layer 130.

The laser cutting method is conducive to cut the insulation layer 122 under low cutting stress conditions, thereby reducing the possibility of forming an undesirable chipping or cracking flaw on the exposed side surface 124 of the insulation layer 122. The dicing saw cutting method is conducive to cut the substrate layer 110 whose material strength is higher than that of the insulation layer 122. According to some embodiments of the present disclosure, the roughness of the third side surface 117 of the substrate layer 110 formed in the second cutting step may be smaller than the roughness of the side surface 124, the second side surface 131 and the first side surface 115 of the substrate layer 110 formed in the first cutting step. The width W118 of the opening 118 smaller than the width W114 of the groove 114 is conducive to reduce the probability of influence on the protection layer 130 and on the circuit structure 120 when cutting the substrate layer 110, for example, less influence on the profile of the first side surface 115, of the side surface 124 and of the second side surface 131 formed through the first cutting step.

The circuit structure 120 may have an inclined side surface 124 to indicate that there is an angle θ1 between the side surface 124 of the circuit structure 120 and the normal direction (i.e. the Z direction) of the substrate layer 110. For example, in a schematic cross-sectional view, to draw an extension line perpendicular to the surface of the substrate layer 110 from an intersection point P1 on the side surface 124 contacting the surface of the substrate layer 110 along the normal direction of the substrate layer 110 (i.e. the Z direction) and the extension line passing through the intersection point P1, an angle between the extension line and the side surface 124 is the included angle θ1. According to some examples of the present disclosure, θ1 may be from 5° to 45°, that is, 5°≤θ1≤45°. There is another angle θ2 between the third side surface 117 of the substrate layer 110 and the normal direction of the substrate layer 110. For example, in a schematic cross-sectional view, to draw an extension line perpendicular to the surface of the substrate layer 110 (i.e. the Z direction) from an intersection point P2 on the third side surface 117 of the substrate layer 110 and on the bottom surface 112 of the substrate layer 110 and the extension line passing through the intersection point P2, an angle between the extension line and the third side surface 117 is the included angle θ2. In some embodiments of the present disclosure, θ2 may be smaller than θ1, that is, θ2<θ1. For example, the extension line is substantially a normal direction of the substrate layer 110.

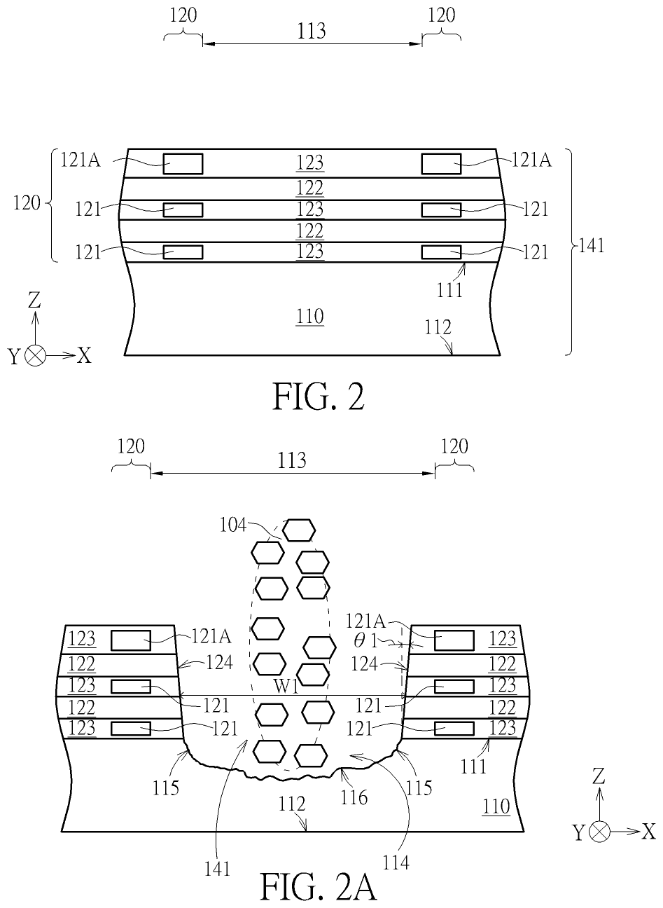

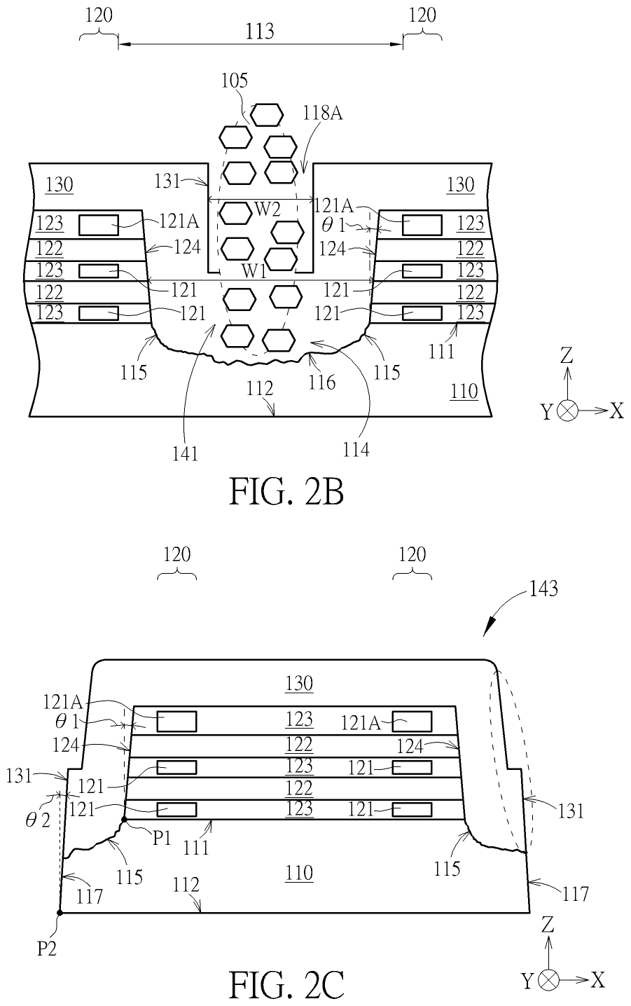

FIG. 2, FIG. 2A, FIG. 2B and FIG. 2C are respectively schematic process diagrams of a variant embodiment of a method for forming an electronic device according to the present disclosure. FIG. 2, FIG. 2A, FIG. 2B and FIG. 2C respectively represent the component structures in a schematic cross-sectional view. The components and axial directions shown in FIG. 2, in FIG. 2A, in FIG. 2B and in FIG. 2C generally correspond to the components and to the axial directions shown in FIG. 1, in FIG. 1A, in FIG. 1B and in FIG. 1C, so similar reference characters refer to similar components in the drawings. Please refer to FIG. 2. The manufacturing method of an electronic device of the present disclosure includes first providing a substrate layer 110. The substrate layer 110 may include a wafer, which may include, for example, a silicon-based material, a doped silicon material, a gallium nitride material or other semiconductor materials, glass, ceramics, an organic material, a combination of the above, or other suitable materials, but the present disclosure is not limited thereto. The substrate layer 110 has two opposite sides, such as a first side 111 serving as an active surface and an opposite second side 112. According to some embodiments, a circuit structure 120 is disposed on one side of the substrate layer 110. FIG. 2 illustrates that two sets of circuit structures 120 are respectively disposed on the first side 111 of the substrate layer 110, but the present disclosure is not limited thereto. A cutting region 113 is provided between the circuit structures 120 to define the cutting location of adjacent circuit structures 120. According to some embodiments, a cutting step may be carried out in the cutting region 113 through some suitable cutting methods to separate the substrate layer 110 and the circuit structure 120, thereby obtaining a plurality of chips.

The circuit structure 120 may include at least one metal layer 121, at least one insulation layer 122, and at least one insulation layer 123. The metal layer 121 may also include a metal pad 121A disposed on the top layer to serve as an input/output terminal bonding pad. FIG. 2 illustrates that two metal layers 121 and one metal pad 121A are respectively embedded in three insulation layers 123, but the present disclosure is not limited thereto. Please refer to the above for details of the metal layer 121, of the insulation layer 122, or of the insulation layer 123 so they are not elaborated again. As shown in FIG. 2 to FIG. 2C, the cutting region 113 passes through the insulation layer 123 of the circuit structure 120 only and does not pass through the metal layer 121.

Second, as shown in FIG. 2A, a first cutting step may be carried out in the absence of a protection layer. The first cutting step may cut the insulation layer 122 and the insulation layer 123 of the circuit structure 120 from the cutting region 113 and expose a portion of a side of the insulation layer 122. After cutting a portion of the substrate layer 110, a portion of the substrate layer 110 disposed in the cutting region 113 is exposed to form the groove 114 and the first side surface 115. For example, the circuit structure 120 may be cut by laser. The groove 114 has a width W1 along the X direction. According to some examples of the present disclosure, the first cutting step may cut the circuit structure 120 to form a continuous inclined side surface 124, and cut the exposed portion of the substrate layer 110 to form the groove 114 with a curved concave surface 116 and a curved edge adjacent to the metal layer 121, namely the first side surface 115, where the first side surface 115 may have a wavy profile. According to some examples of the present disclosure, the first cutting step may reduce the possibility of forming an undesirable chipping or cracking flaw on the exposed side surface 124 of the insulation layer 122.

Please continue to refer to FIG. 2B. The protection layer 130 is attached to the circuit structure 120 and to the curved concave surface 116 of the exposed portion of the substrate layer 110 to make the groove 114 shown in FIG. 2A reduced to a notch 118A. The notch 118A has a width W2 along the X direction. The protection layer 130 may fill the groove 114 in a conformal manner, and cover the upper surface and continuous inclined side surfaces 124 of the circuit structure 120 to protect the circuit structure 120 on the substrate layer 110 and cover the curved concave surface 116 of the exposed portion of the substrate layer 110. For example, the protection layer 130 may cover the surface of the circuit structure 120 and the curved concave surface 116 of the exposed portion of the substrate layer 110 along the topography of the circuit structure 120. Please refer to the above description for the details of the protection layer 130 so they are not elaborated again.

After the circuit structure 120 covered with the protection layer 130, a second cutting step proceeds in the presence of the protection layer 130. The second cutting step may continue to cut the protection layer 130 and the substrate layer 110 from the notch 118A along the cutting region 113 to separate the protection layer 130 and the substrate layer 110 so that each two sets of the circuit structures 120 are individually separated from a plurality sets of circuit structure 120 on the first side 111 of the substrate layer 110 through this singulation step to form a plurality of chips 143, as shown in FIG. 2C. According to some examples of the present disclosure, the notch 118A is disposed in the groove 114, so the width W2 of the notch 118A along the X direction is smaller than the width W1 of the groove 114 along the X direction. According to some examples of the present disclosure, the second cutting step may cut the substrate layer 110 to form the third side surface 117 and cut the protection layer 130 to form the second side surface 131 while the third side surface 117 connects to the second side surface 131. According to some other examples of the present disclosure, the second cutting step reduces the impact of the second cutting step on the profile of the first side surface 115 and on the profile of the side surface 124 formed through the first cutting step in the presence of the protection layer 130, but the present disclosure is not limited thereto.

Different cutting conditions may be used to respectively carry out the first cutting step and the second cutting step. That is to say, according to some embodiments of the present disclosure, the first cutting step is different from the second cutting step. For example, the wavelength or energy of the laser 104 used in the first cutting step may be different from the wavelength or from the energy of laser 105 used in the second cutting step. For example, the laser 104 used in the first cutting step may be a laser of a wavelength of 540 nm, of a wavelength of 1075 nm or other suitable wavelengths, and the laser 105 used in the second cutting step may be a laser of a wavelength of 355 nm, or a laser of a wavelength less than 450 nm, but the present disclosure is not limited thereto. Through the design of the above steps, cutting debris may be reduced, but the present disclosure is not limited thereto.

The circuit structure 120 may have an inclined side surface 124 after cutting to indicate that there is an angle θ1 between the side surface 124 of the circuit structure 120 and the normal direction (i.e. the Z direction) of the substrate layer 110. According to some examples of the present disclosure, θ1 may be from 5° to 45°, that is, 5°≤θ≤45°. For example, in a schematic cross-sectional view, to draw an extension line perpendicular to the surface of the substrate layer 110 from an intersection point P1 on the side surface 124 contacting the surface of the substrate layer 110 along the normal direction of the substrate layer 110 (i.e. the Z direction) and the extension line passing through the intersection point P1, an angle between the extension line and the side surface 124 is the included angle θ1.

There is another angle θ2 between the third side surface 117 of the substrate layer 110 and the normal direction of the substrate layer 110. For example, in a schematic cross-sectional view, to draw an extension line perpendicular to the normal direction of the substrate layer 110 (i.e. the Z direction) from an intersection point P2 on the third side surface 117 of the substrate layer 110 and on the bottom surface 112 of the substrate layer 110 and the extension line passing through the intersection point P2, an angle between the extension line and the third side surface 117 is the included angle θ2. In some embodiments of the present disclosure, θ2 may be smaller than θ1, that is, θ2<θ1. The protection layer 130 after cutting may have an inclined second side surface 131, wherein the second side surface 131 may have a stepped profile, that is, in a schematic cross-sectional view, as shown by the dotted line in FIG. 2C, it includes at least an extension direction of a segment of a profile is different from the extension direction of other profiles. Through the above design, the surface area of the protection layer 130 is increased, for example, to improve the bonding strength between the protection layer 130 and subsequent film layers, but the present disclosure is not limited thereto. The substrate layer 110 after cutting may have an inclined third side surface 117, and there is an angle θ2 between the third side surface 117 and the normal direction of the substrate layer 110. For example, in a schematic cross-sectional view, to draw an extension line perpendicular to the surface of the substrate layer 110 (i.e. the Z direction) from an intersection point P2 on the third side surface 117 of the substrate layer 110 and on the bottom surface 112 of the substrate layer 110 and the extension line passing through the intersection point P2, an angle between the extension line and the third side surface 117 is the included angle θ2. In some embodiments of the present disclosure, θ2 may be smaller than θ1, that is, θ2<θ1. Through the above cutting methods, cutting debris may be reduced, or through the above design, the risk of causing of cracking of other film layers in subsequent packaging steps may be reduced.

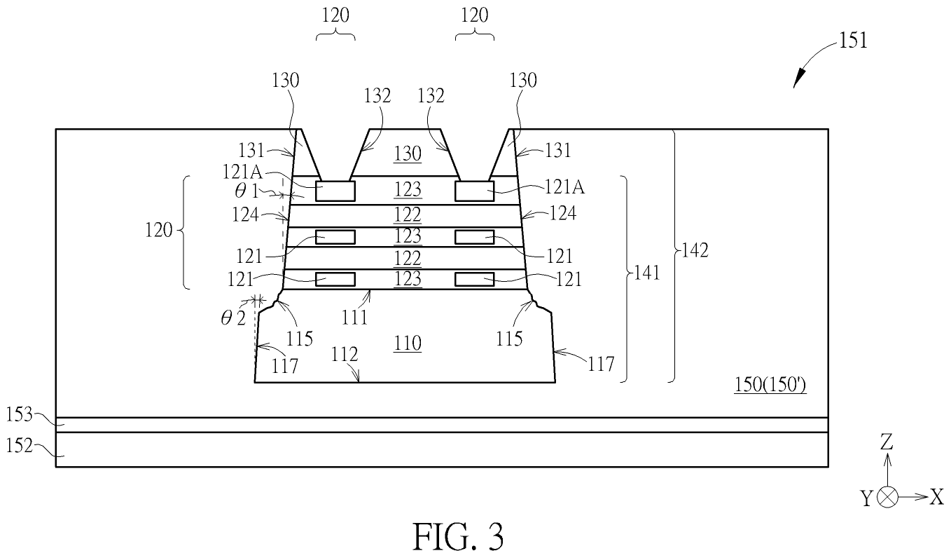

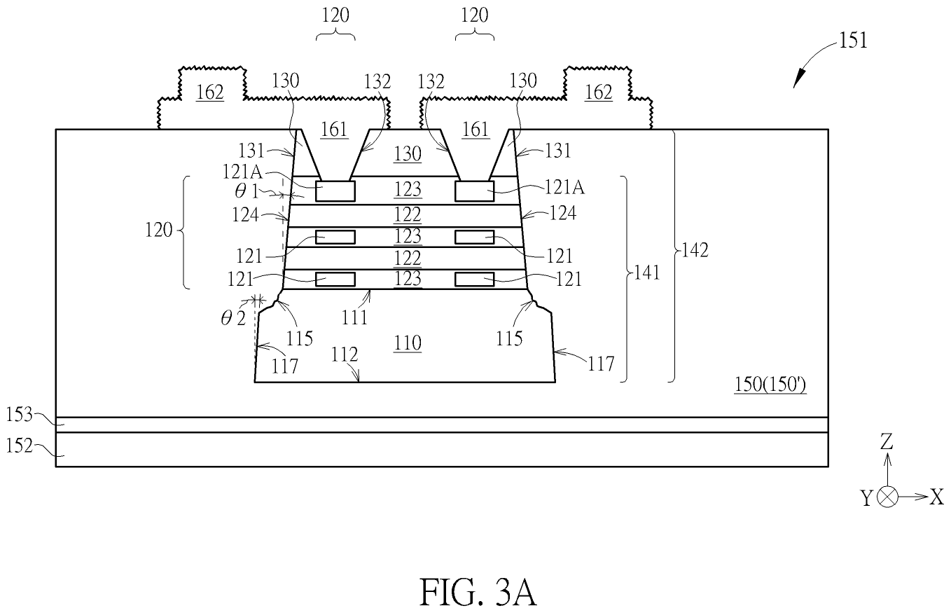

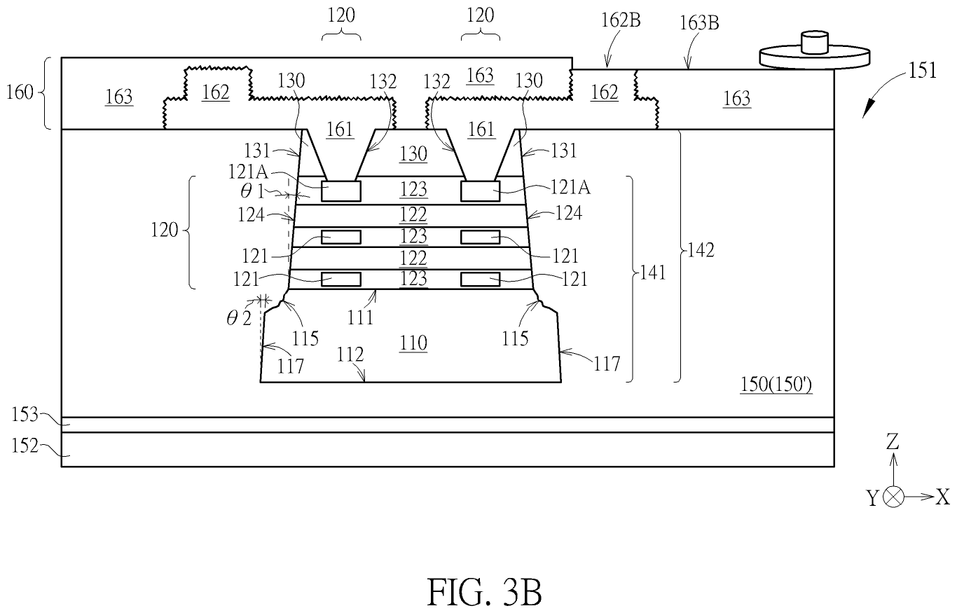

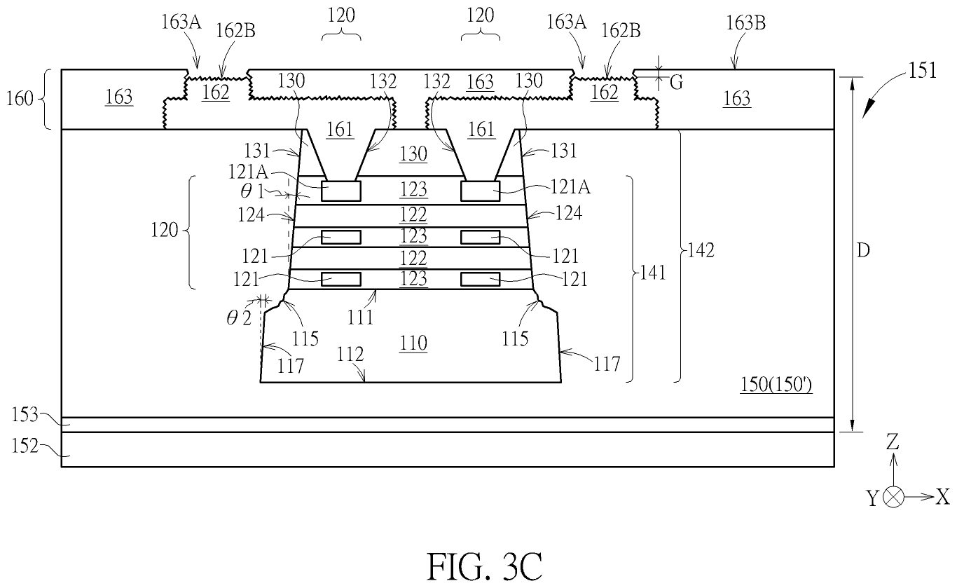

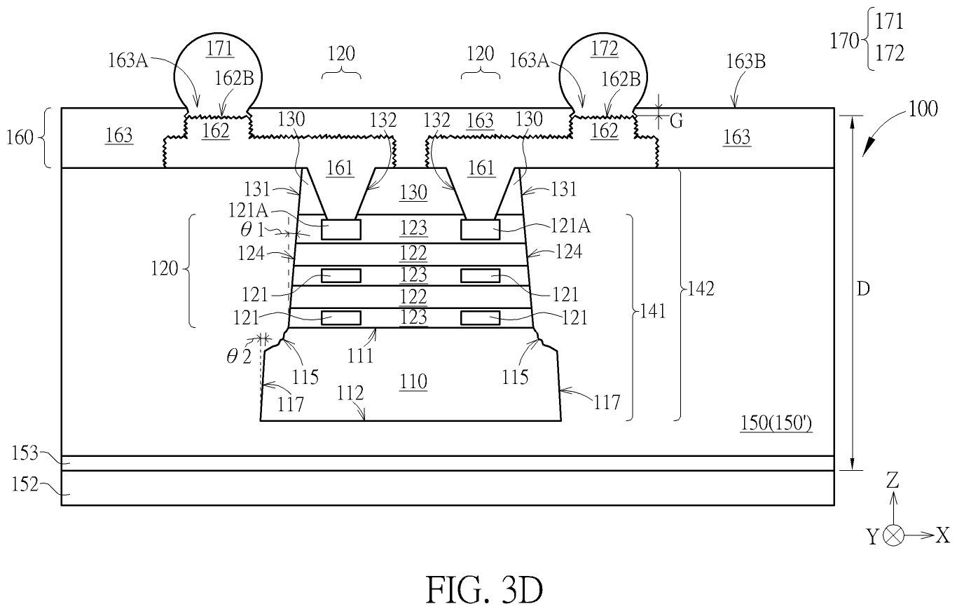

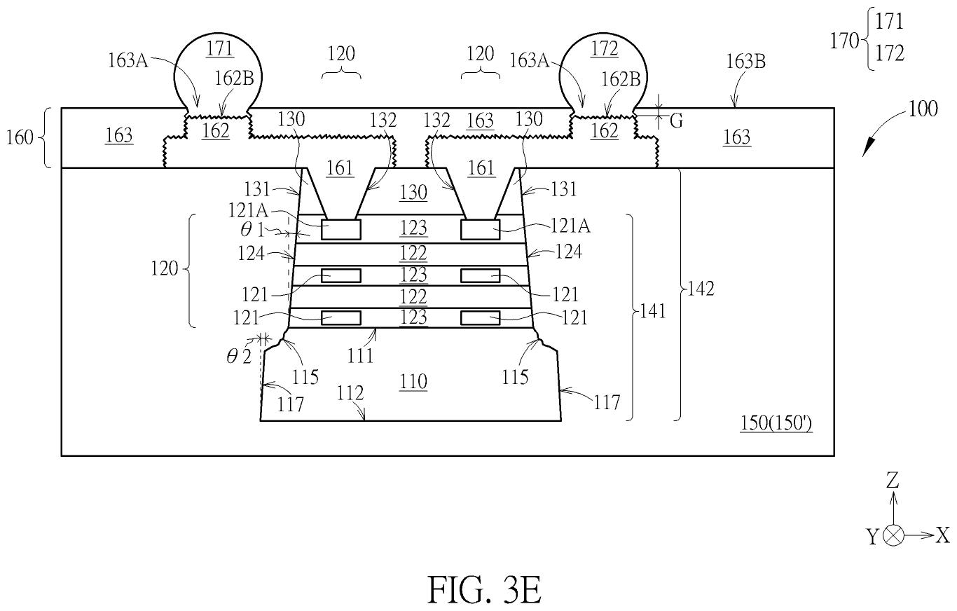

A plurality of chips 142 or a plurality of chips 143 obtained by the above-mentioned methods of forming an electronic device may further go through the steps of packaging and of forming a redistribution structure layer. The chip 142 or the chip 143 may respectively include a substrate layer 110, a circuit structure 120 disposed on the active surface of the substrate layer 110, and a protection layer 130. FIG. 3, FIG. 3A, FIG. 3B, FIG. 3C, FIG. 3D and FIG. 3E respectively illustrate a process diagram of an embodiment of a method for forming an electronic device by subsequent packaging and forming a redistribution structure layer according to the present disclosure. FIG. 3, FIG. 3A, FIG. 3B, FIG. 3C, FIG. 3D and FIG. 3E respectively illustrate the component structures in schematic cross-sectional views, and the chip 142 is taken as an illustration, but the present disclosure is not limited thereto. First, as shown in FIG. 3, an encapsulation layer 150′ is provided to package the chip 142 disposed on the first carrier (not shown). For example, at least one chip 142 is transferred to the first carrier, and the encapsulation material 150′ is provided to encapsulate or surround at least one chip 142. After curing the encapsulation material 150′, a molding layer 150 covering and directly contacting the first carrier and the chip 142 is formed. According to some embodiments, the molding layer 150 surrounds the first carrier and the chip 142 such that the chip 142 is buried in the molding layer 150, also, the molding layer 150 is in contact with at least a portion of the second side surface 131 of the protection layer 130. For example, when transferring the chip 142 to the first carrier, the active surface of the chip may face the first carrier, wherein method of transferring including pick and place or other suitable method, but the present disclosure is not limited thereto. In other words, the protection layer 130 may be provided toward the first carrier, and then the molding layer 150 is formed to cover the chip 142, that is, the thickness of the molding layer 150 may be greater than the thickness of the chip 142 to form a packaging structure 151. For example, in a cross-sectional view, the molding layer 150 is disposed to directly contact at least two sides of the chip 142 to form the packaging structure 151. Before provided, the molding layer 150 may be an encapsulation material in a form of a soft film, of powder or of liquid. For example, it may include a pre-polymerized epoxy molding compound (EMC) material, but the present disclosure is not limited thereto. After the pre-polymerized epoxy molding compound material is cured, it may become a cured molding layer 150, but the present disclosure is not limited thereto. The molding layer 150 which directly contacts a corresponding component may, for example, help prevent moisture or oxygen from contacting or penetrating the corresponding component, that is, improve the weather resistance of the electronic device, but the present disclosure is not limited thereto.

To be continued, as shown in FIG. 3, after packaging the chip 142 with the molding layer 150, the packaging structure 151 may be turned over so that the protection layer 130 shown in FIG. 3 is placed upward. That is to say, after the packaging structure 151 is turned over, the molding layer 150 exposes the protection layer 130. The steps of turning over the packaging structure 151 may include, optionally, a step of providing a second carrier 152 on one side of the packaging structure 151 opposite to the first carrier and a step of removing the first carrier. For example, in some examples, the steps of adding the second carrier 152 and of turning over the first carrier may be carried out prior to the step of removing the first carrier. The first carrier and the second carrier 152 may be respectively adjacent to one side of the packaging structure. The second carrier 152 is further provided with a de-bonding layer 153 so that the molding layer 150 is temporarily fixed to the second carrier 152 via the de-bonding layer 153. After the step of removing the first carrier, the protection layer 130 may be exposed. Then, a portion of the protection layer 130 is removed by appropriate patterning steps to form a through hole 132, and the metal pads 121A of the metal layer 121 covered by the protection layer 130 and by the insulation layer 123 are respectively exposed through the through hole 132. The method of patterning the protection layer 130 includes, but is not limited to, photolithography, laser, a combination of the above, or other suitable methods. According to some embodiments, the step of patterning the protection layer 130 to expose the metal pads 121A may be carried our prior to the singulation step, but the present disclosure is not limited thereto.

Next, a redistribution structure layer may be provided to be electrically connected to the metal pads 121A of the circuit structure 120 in the chip 142. The method of forming the redistribution structure layer includes providing a stack including at least one insulation layer and at least one conductive layer, including processes such as photolithography, etching, surface treatment, laser, and electroplating. The surface treatment includes roughening the surface of the insulation layer or the surface of the conductive layer to improve the bonding ability. The following describes a method of forming the redistribution structure layer, but the present disclosure is not limited thereto.

As shown in FIG. 3A, for example, in some examples, the first metal layer 161 is provided to be respectively electrically connected to the metal pads 121A for use as the input and output terminal bonding pads of the chip 142. For example, a bulk of seed layer (not shown) may be formed on the surfaces of the protection layer 130 and of the molding layer 150 by sputtering or by deposition. The materials of the seed layer may include titanium, copper, tantalum, nickel, a combination of the above or other suitable materials. Next, a photoresist material (not shown) is formed on the bulk of the seed layer, a conductive layer of materials which may include copper, nickel, gold, titanium, molybdenum, aluminum or other suitable materials is formed by electroplating or chemical plating after the photoresist material (not shown) is patterned by exposure and development. After the steps of removing the photoresist or of etching, the first metal layer 161 is formed. Further, the first metal layer 161 may be a composite layer of a seed layer and a conductive layer. By forming a seed layer between the conductive layer and the protection layer 130, the bonding ability between the first metal layer 161 and the protection layer 130 may be enhanced, or between the first metal layer 161 and molding layer 150 may be enhanced. The above steps are repeated to form the second metal layer 162 on the first metal layer 161. Wherein, the photoresist material may be an adhered dry film, or a positive photoresist material or a negative photoresist material patterned by exposure and development to help define the pattern of the first metal layer 161 and the location of the second metal layer 162 which serves as a stud.

In some examples, the first etching process may proceed to be carried out to roughen the first metal layer 161 and/or the second metal layer 162 respectively, for example, to roughen the surface of the metal layer 161 and/or the surface of the second metal layer 162 after the first metal layer 161 and the second metal layer 162 are formed. For example, the first metal layer 161 and the second metal layer 162 are immersed in an aqueous etchant to carry out the first etching process so that the surface of the first metal layer 161 or the surface of the second metal layer 162 respectively has a rough surface, to respectively result in uneven bulges or recesses. The etching process may include chemical etching, laser etching, a combination of the above, or other suitable roughening methods, but the present disclosure is not limited thereto.

Then, as shown in FIG. 3B, a first insulation layer 163 is first provided to cover the protection layer 130, the molding layer 150, the first metal layer 161 and the second metal layer 162. For example, the first insulation layer 163 may be in direct contact with the protection layer 130, with the molding layer 150, with the first metal layer 161 and with the second metal layer 162. The first metal layer 161, the second metal layer 162 and the first insulation layer 163 together form the redistribution structure layer 160. In particular, the first insulation layer 163 is in direct contact with the bulges of the roughened surface of the first metal layer 161 or of the surface of the second metal layer 162 or goes deep into the recesses. For example, the above design may help increase the bonding strength of the first metal layer 161 and of the second metal layer 162 to the first insulation layer 163, reduce the risk of cracking between film layers owing to the differences in the thermal expansion coefficients, or help improve the reliability of electronic devices.

Please proceed to the illustrations in FIG. 3B. According to some embodiments of the present disclosure, a portion of the first insulation layer 163 may be removed to expose the second metal layer 162. For example, grinding may be used to remove a portion of the first insulation layer 163 of the redistribution structure 160 and thereby exposing the second metal layer top surface 162B of the second metal layer 162 of the redistribution structure 160. When the second metal layer top surface 162B is removed by grinding, it simultaneously remove the roughened bulges or recesses which are previously formed on the second metal layer top surface 162B by etching, and the second metal layer top surface 162B is polished up and is flush with the polished first insulation layer top surface 163B.

Then, as shown in FIG. 3C, according to some embodiments of the present disclosure, a second etching process, such as chemical etching, laser etching, micro-etching process or a combination thereof, may be further carried out to remove a portion of the second metal layer 162 to form a cavity 163A after a portion of the first insulation layer 163 is removed, thereby reducing the vertical distance D along the Z direction between the second metal layer top surface 162B and the second carrier 152 so that there is a gap G, for example 1 μm to 10 μm, between the first insulation layer top surface 163B and the second metal layer top surface 162B and the roughness of the second metal layer top surface 162B is increased. Through the second etching process, the second metal layer top surface 162B is no longer flush with the first insulation layer top surface 163B after the grinding step to define the cavity 163A, so as to said, the gap G is between the second metal layer top surface 162B and the first insulation layer top surface 163B at the same time the roughness of the second metal layer top surface 162B is increased, and/or the second metal layer top surface 162B becomes a concave surface. For example, the packaging structure 151 may be immersed in an aqueous etchant, or the aqueous etchant may be applied to the second metal layer top surface 162B to carry out the second etching process to selectively remove a portion of the second metal layer top surface 162B, thereby reducing the vertical distance D along the Z direction between the second metal layer top surface 162B and the second carrier 152. After the second etching process, the first redistribution structure layer 160 may be obtained. For example, the first redistribution structure layer 160 may include a first metal layer 161, a second metal layer 162 and a first insulation layer 163, and is disposed on the packaging structure 151. In some examples, the second metal layer top surface 162B may be flat after the second etching process. In other examples, the second metal layer top surface 162B may be a curved surface after the second etching process. In still other examples, the second metal layer top surface 162B may be smooth after the second etching process. In still other examples, the second metal layer top surface 162B may be an uneven and rough with a surface roughness after the second etching process.

Subsequently, as shown in FIG. 3D, after the second etching process, the bonding component 170 may follow to be formed so that the bonding component 170 corresponds to the second metal layer 162 and is disposed in the recess 163A which is together defined by the first insulation layer 163 and by the second metal layer top surface 162B. For example, the bonding component 170 may be formed through a ball drop step and through a reflow step so that the bonding component 170 is disposed to correspond to and overlap the metal layer of the redistribution structure layer 160. According to some examples of the present disclosure, the above “disposed to correspond to” may mean that the bonding component 170 is in direct contact with at least a portion of the corresponding element. For example, in the cross-sectional view, the bonding component 170 is disposed in direct contact with the second metal layer top surface 162B. According to some embodiments, the roughened second metal layer top surface 162B may be beneficial to increase the contact area of the interface between the bonding component 170 and the second metal layer top surface 162B. In some embodiments of the present disclosure, the bonding component 170 may include a bump, and the bump may be a solder ball, for example. FIG. 3D illustrates that the solder balls 171 and 172 included in the bonding component 170 may be respectively disposed to correspond to different second metal layer top surfaces 162B, but the present disclosure is not limited thereto. The bonding component 170 may include tin, nickel, gold, a combination of the above, or other suitable materials, but the present disclosure is not limited thereto.

According to some examples of the present disclosure, solder balls or other bonding components may be electrically connected to each chip or electronic unit through a redistribution structure. The redistribution structure may include at least one conductive layer and at least one insulation layer, or may redistribute wires and/or further increase the fan-out area of wires, or different electronic components may be electrically connected to each other through the redistribution structure. For example, in a cross-sectional view, along a direction perpendicular to the normal direction of the substrate layer 110 (Z direction), the pitch between two adjacent contact pads of the redistribution structure contacting one end of the chip is smaller than the pitch between two adjacent contact pads of the circuit structure far away from one end of the chip, that is, the distance between adjacent first metal layers 161 is smaller than the distance between adjacent second metal layers 162. Therefore, the wire fan-out may be adjusted through the circuit structure, but the present disclosure is not limited thereto.

Next, as shown in FIG. 3E, the de-bonding layer 153 may be removed by heating, laser, or other methods to remove the second carrier 152 after the bonding components 170 are formed. According to some examples of the present disclosure, it includes to further cut the redistribution structure layer 160 and the packaging structure 151 to obtain the electronic device 100 of the present disclosure. The electronic device 100 of the present disclosure may include at least one chip 141, a protection layer 130, a molding layer 150, a redistribution structure layer 160 and a bonding component 170. The chip 141 may include the substrate layer 110 which may include, for example, a silicon-based material, a doped silicon material or a gallium nitride material, but the present disclosure is not limited thereto. The substrate layer 110 may have two opposite sides, such as a first side 111 of the active surface, a second side 112 and a first side surface 115 connecting the active surface. According to some embodiments, the first side 111 of the active surface of the substrate layer 110 is provided with a circuit structure 120, so that the chip 141 may include the substrate layer 110 and the circuit structure 120 disposed on one side of the substrate layer 110.

The circuit structure may include at least one metal layer 121, at least one dielectric layer 122 and at least one insulation layer 123. The dielectric layer 122 may include a porous material of a low dielectric constant, such as a low dielectric constant layer having a porous material of a dielectric constant lower than 2.4, a porous material of a dielectric constant lower than 2.0 or a porous material of a dielectric constant lower than 1.9, but the present disclosure is not limited thereto.

The protection layer 130 may be disposed on the active surface of the substrate layer 110 of the chip 141, such as on the first side 111. In addition, the protection layer 130 may have a second side surface 131. The molding layer 150 surrounds the chip 141 and the protection layer 130. In a cross-sectional view, the molding layer 150 may be in direct contact with at least two sides of the chip 141, such as the first side surface 115 and the third side surface 117 of the substrate layer 110, and the side surface 124 of the circuit structure 120. According to some embodiments of the present disclosure, the roughness of the first side surface 115 and the roughness of the third side surface 117 of the chip 141 are different, the roughness of the first side surface 115 and the roughness of the second side surface 131 are different, and the roughness of the third side surface 117 and the roughness of the second side surface 131 of the chip 141 are different. For example, the roughness of the third side surface 117 is smaller than the roughness of the first side surface 115. For example, to observe with an electron microscope, the difference in wavy undulations of the first side surface 115 is greater than the difference in wavy undulations of the third side surface 117. For example, the roughness of the second side surface 131 is greater than the roughness of the third side surface 117, but the present disclosure is not limited thereto. For example, the roughness of the second side surface 131 is smaller than the roughness of the first side surface 115, but the present disclosure is not limited thereto. According to other embodiments of the present disclosure, the side surface of the low dielectric constant layer aligns with the side surface of the protection layer. For example, the protection layer 130 has the second side surface 131, and the dielectric layer 122 in the circuit structure 120 has the side surface 124. The two side surfaces are formed in the same cutting method so they align with each other. For example, according to some embodiments, the side surface 131 and the side surface 124 may be regarded to align with each other when an included angle between the side surface 131 and the side surface 124 is less than or equal to 10°. According to some embodiments, the side surface of each film layer may not align with each other.

The first redistribution structure layer 160 may be disposed on the molding layer 150 and on the protection layer 130. The first redistribution structure layer 160 may include one or more sets of conductive layers, such as one or more sets of first metal layers 161 and one or more sets of second metal layers 162, and one or more sets of first insulation layers 163. The redistribution structure layer may be electrically connected to the chip 141 via the conductive layer, for example, electrically connected to the plurality of metal pads 121A for use as the input/output terminal bonding pads in the circuit structure 120 via the first metal layer 161 so that the redistribution structure layer is electrically connected to the chip 141. The bonding component 170 may be provided to overlap a conductive layer of the redistribution structure layer 160. For example, the bonding component 170 may be disposed to correspond to the second metal layer 162 so that the bonding component 170 may be electrically connected to the chip 141 via the redistribution structure layer 160.

According to some embodiments of the present disclosure, the chip 141 further includes a chip back such as a second side 112 opposite to the active surface such as the first side 111. The second side 112 may be connected to the active surface via the third side surface 117 and the first side surface 115. According to some other embodiments of the present disclosure, the roughness of the third side surface 117 is smaller than the roughness of the first side surface 115. Through the above design, the bonding strength may be increased, thereby further reducing the risk of cracking of the interfaces between different film layers, but the present disclosure is not limited thereto.

According to some embodiments of the present disclosure, the surface of the conductive layer in the redistribution structure may be not flush with the insulation layer which surrounds the conductive layer in the redistribution. For example, the second metal layer top surface 162B in the first redistribution structure layer 160 may be not flush with the first insulation layer top surface 163B which surrounds the second metal layer 162 to define the cavity 163A, but the present disclosure is not limited thereto.

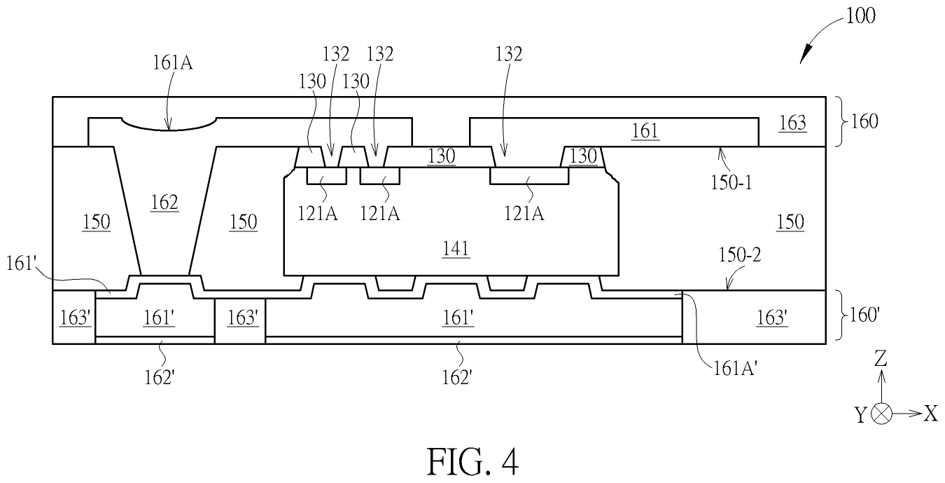

FIG. 4 illustrates a schematic cross-sectional view of a variant embodiment corresponding to the electronic device 100 illustrated in FIG. 3B. Some components are omitted to facilitate the description. According to some embodiments of the present disclosure, the electronic device 100 may further include a first redistribution structure layer 160 and a second redistribution structure layer 160′. The first redistribution structure layer 160 and the second redistribution structure layer 160′ may be respectively disposed to correspond to two opposite sides of the molding layer 150, such as the first side 150-1 and the second side 150-2. The first redistribution structure layer 160 may include one or more sets of the first metal layers 161 and of the second metal layers 162, and one or more sets of the first insulation layer 163 corresponding to one or more sets of the first metal layers 161 and of the second metal layers 162. The second redistribution structure layer 160′ may include one or more sets of the first metal layers 161′, of the second metal layers 162′, one or more sets of the second insulation layer 163′ corresponding to one or more sets of the first metal layers 161′ and of the second metal layers 162′, and the seed layer 161A′. The first metal layer 161 may further include a cavity 161A. The first metal layer 161 is respectively electrically connected to a plurality of metal pads 121A for use as the input/output terminal bonding pads of the chip 142. The first insulation layer 163 covers the protection layer 130 of the packaging structure 151 and the first metal layer 161. In addition, the second redistribution structure layer 160′ may be electrically connected to the second metal layer 162 of the first redistribution structure layer 160 via the seed layer 161A′, specifically speaking, to be connected to external components, such as a printed circuit board via the second metal layer 162′, but the present disclosure is not limited thereto.

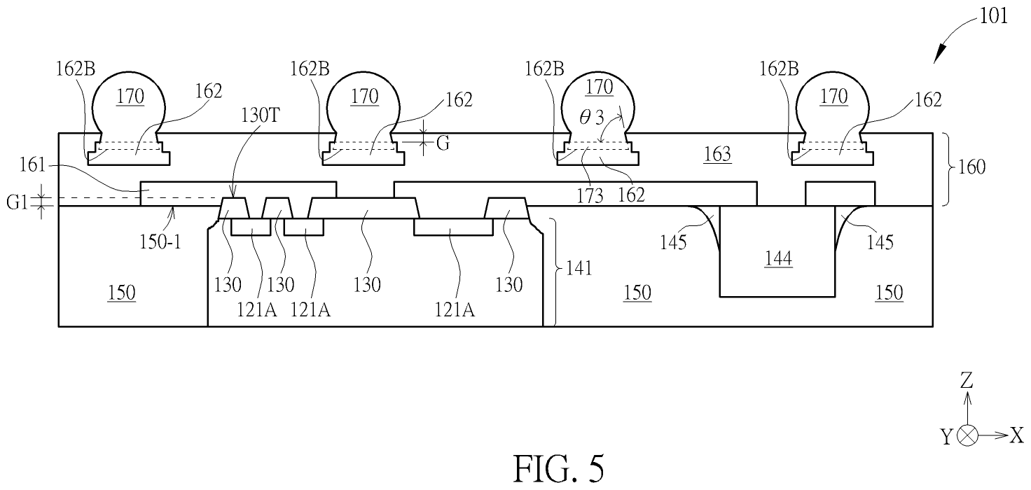

FIG. 5 illustrates a schematic cross-sectional view of a variant embodiment corresponding to the electronic device illustrated in FIG. 3E. Some components are omitted to facilitate the description. Optionally, the electronic device 101 in FIG. 5 may further include an electronic unit 144 in addition to the chip 141. The chip 141 and the electronic unit 144 may respectively be an electronic unit of different functions, and may be electrically connected to each other via the first metal layer 161 of the first redistribution structure layer 160. In some examples, the electronic unit 144 may include an integrated circuit, a memory, a diode, a sensor, a surface mount device (SMD), and/or large scale integration (LSI). The surface mount device may include a passive component, for example, a capacitor, a resistor, but the present disclosure is not limited thereto. The chip 141 may be a die, a semiconductor component, a light emitting diode, a variable capacitance diode, etc. As shown in the figure, a glue layer 145 may be optionally provided around the periphery of the conductive pad which the electronic unit 144 and the first metal layer 161 are connected to. The glue layer 145 may include resin, polymer, or other suitable materials. For example, the glue layer 145 may be an underfill layer. The arrangement of the underfill layer 145 helps improve the reliability of the electronic unit 144. The electronic unit 144 may include conductive pads (not shown) contacting the first metal layer 161, thereby having the electronic unit 144 electrically connected to the redistribution structure layer 160, wherein the conductive pads include copper, tin, silver, alloys, a combination of the above, or other suitable conductive materials, but the present disclosure is not limited thereto.

According to some examples of the present disclosure, the top surface 130T of the protection layer 130 and the first side 150-1 of the molding layer 150 may be unequal in height and have a gap G1. For example, along the Z direction, the gap G1 may be 0.05 μm to 10 μm (0.05 μm≤G1≤10 μm), or the gap G1 may be 1 μm to 5 μm (1 μm≤G1≤5 μm), but the present disclosure is not limited thereto. Through the gap design between the protection layer 130 and the molding layer 150, the contact area between the protection layer 130 and the molding layer 150 may be increased so that the protection layer 130 and the molding layer 150 may engage with each other to reduce the risk of chip drifting during the packaging step, but the present disclosure is not limited thereto. According to some other examples of the present disclosure, the bonding component 170 is disposed in the cavity 163 and overlaps the second metal layer 162. There is an included angle θ3 between the bonding component 170 and the second metal layer 162. The included angle θ3 may be 15° to 60°, that is, 15°≤θ3≤60°, but the present disclosure is not limited thereto. That is to say, the first insulation layer 163 is disposed on a portion of the bonding component 170 when there is an included angle θ3 between the bonding component 170 and the second metal layer 162 so that a portion of the bonding component 170 is disposed between the first insulation layer 163 and the second metal layer 162. Through the above design, the risk of cracking of the bonding component 170 may be reduced, but the present disclosure is not limited thereto.

Some embodiments of the present disclosure provide a manufacturing method of an electronic device to be able to respectively cut the dielectric layer and the substrate layer through two different cutting methods. The cutting conditions of the first cutting step may be milder than the cutting conditions of the second cutting step. For example, the dielectric layer is cut under low cutting stress conditions thereby reducing the possibility of forming an undesirable chipping or cracking flaw on the exposed side surfaces of the dielectric layer. The second cutting step is beneficial to cut the substrate layer whose material strength is higher than that of the dielectric layer so that the roughness of the side surface formed in the first cutting step may be different from the roughness of the side surfaces formed in the second cutting step. The manufacturing methods of an electronic device provided by some embodiments of the present disclosure are beneficial to reduce the possibility of the obtained chips, packaging structures, dies, or the dielectric constant material layers in the electronic device to be prone to chipping or cracking so that it is conducive to improve the structural stability and reliability of chips, of packaging structures, of dies, or of electronic devices.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method of manufacturing an electronic device, comprising:
providing a substrate layer;
providing a circuit structure on one side of the substrate layer;
providing a protection layer on the circuit structure;
performing a first cutting step to cut the protection layer to expose a portion of the substrate layer; and
performing a second cutting step to cut the substrate layer to form a plurality of chips,
wherein the first cutting step is different from the second cutting step.

2. The method of manufacturing an electronic device of claim 1, further comprising:
transferring at least one of the plurality of chips to a carrier.

3. The method of manufacturing an electronic device of claim 1, further comprising:
providing an encapsulation layer to surround the at least one of the plurality of chips to form a packaging structure.

4. The method of manufacturing an electronic device of claim 3, further comprising:
turning the packaging structure over and forming a redistribution structure layer, wherein the redistribution structure layer is electrically connected to the packaging structure.

5. The method of manufacturing an electronic device of claim 4, further comprising:
grinding the redistribution structure layer until a portion of a metal layer of the redistribution structure layer is exposed.

6. The method of manufacturing an electronic device of claim 5, further comprising:
providing a bonding component to be arranged to correspond to the metal layer.

7. The method of manufacturing an electronic device of claim 1, wherein, the substrate layer forms a first side surface 115 at a first cutting region and the protection layer forms a second side surface 131 at the first cutting region after performing the first cutting step.

8. The method of manufacturing an electronic device of claim 7, wherein, the substrate layer forms a third side surface at a second cutting region after performing the second cutting step, and a roughness of the third side surface of the substrate layer is smaller than a roughness of the first side surface.

9. The method of manufacturing an electronic device of claim 7, wherein, the substrate layer forms a third side surface at a second cutting region after performing the second cutting step, and a roughness of the third side surface of the substrate layer is different from a roughness of the second side surface of the protection layer.

10. The method of manufacturing an electronic device of claim 1, wherein performing the first cutting step comprises cutting a portion of the substrate layer.

11. The method of manufacturing an electronic device of claim 1, wherein the first cutting step comprises laser cutting, and the second cutting step comprises dicing saw cutting.

12. The method of manufacturing an electronic device of claim 1, wherein the circuit structure comprises a low dielectric constant layer, and the first cutting step comprises cutting the low dielectric constant layer and exposing a portion of a side of the low dielectric constant layer.

13. The method of manufacturing an electronic device of claim 12, wherein a surface of exposed the low dielectric constant layer aligns with a surface of exposed the protection layer.

14. An electronic device, comprising:
a chip having an active surface and a first side surface connected to the active surface;
a protection layer disposed on the active surface of the chip and having a second side surface;
a molding layer surrounding the chip and the protection layer, wherein at least a portion of the second side surface is in contact with the molding layer; and
a redistribution structure layer disposed on the molding layer and on the protection layer, and electrically connected to the chip, wherein, a roughness of the first side surface is different from a roughness of the second side surface.

15. The electronic device of claim 14, wherein the chip further comprises a second side opposite to the active surface and a third side surface, the third side surface connects the first side surface and the second side, and a roughness of the third side surface is smaller than the roughness of the first side surface.

16. The electronic device of claim 14, further comprising:
a bonding component provided to overlap a metal layer of the redistribution structure layer.

17. The electronic device of claim 16, wherein there is a gap between a top surface of the metal layer and a top surface of an insulation layer of the redistribution structure layer surrounding the metal layer.

18. The electronic device of claim 14, wherein the chip comprises a substrate layer and a circuit structure disposed on one side of the substrate layer.

19. The electronic device of claim 18, wherein the circuit structure comprises a low dielectric constant layer, and a side surface of the low dielectric constant layer aligns with the second side surface of the protection layer.

20. The electronic device of claim 18, wherein an angle between the second side surface and a normal direction of the substrate layer is smaller than an angle between the first side surface and the normal direction.
